(19) United States
(12) Patent Application Publication
(10) Pub. No.: US 2026/0277096 A1
(43) Pub. Date: Sep. 17, 2026

(54) METHOD AND DEVICE FOR CAPTURING IMAGES OF MICRO- AND/OR NANOSTRUCTURES

(71) Applicant: Carl Zeiss SMT GmbH, Oberkochen (DE)

(72) Inventors: Ulrich Matejka, Jena (DE); Lutz Brekerbohm, Hardegsen (DE); Dirk Doering, Erfurt (DE)

(21) Appl. No.: 19/563,160

(22) Filed: Mar. 11, 2026

(30) Foreign Application Priority Data
Mar. 12, 2025 (DE) 102025109461.6

(51) Int. Cl. G03F 1/84

(52) U.S. Cl. CPC G03F 1/84

(57) ABSTRACT

A method for capturing images of micro-and/or nanostructures, and to a device designed for carrying out these methods.

The method uses an image capturing unit comprising at least two image capturing sensors arranged in such a way that, from an object guided past the image capturing unit at a constant speed in a predefined direction in the image region, by use of the image capturing sensors, they each successively capture the same region of the surface of the object, wherein the image capturing sensors are controlled by a temporal offset resulting from the speed by use of a predefined factor in such a way that a group of images captured by the individual image capturing sensors in each case image the same region of the surface of the object and can be additively superimposed, comprising:
determining a variable characteristic of the position correspondence of the captured images of the same region in the images of a group captured by the individual image capturing sensors;
if the characteristic variable determined is not optimal: adapting the predefined factor according to the characteristic variable determined.

The device is suitably designed for carrying out this method.

### CROSS-REFERENCE TO RELATED APPLICATION

This application claims benefit under 35 U.S.C. § 119 to German Patent Application 10 2025 109 461.6, filed on Mar. 12, 2025, the entire content of which is incorporated herein by reference.

### TECHNICAL FIELD

The invention relates to a method for capturing images of micro-and/or nanostructures, and to a device designed for carrying out these methods.

### BACKGROUND

Inter alia in semiconductor technology, in particular in the production of semiconductors, objects with micro- and/or nanostructures must be inspected regularly for quality assurance purposes. The objects can be in particular the semiconductors themselves, but also masks used for photolithography during production.

Photolithography is used for producing microstructured components, such as for example integrated circuits. The photolithography process is carried out in what is known as a projection exposure apparatus, which comprises an illumination device and a projection device. The image of a mask (also called “reticle”) illuminated by use of the illumination device is projected in this case by use of the projection device onto a substrate, for example, a silicon wafer, that is coated with a light-sensitive layer (so-called “photoresist”) and arranged in the image plane of the projection device in order to transfer the mask structure to the light-sensitive coating of the substrate. In subsequent production steps, the transferred structure is implemented in the substrate, e.g., by etching.

Even if the projection devices of projection exposure apparatuses have a reduction factor of, e.g., 4:1, the structures of the masks already need to have a high accuracy owing to the advancing miniaturization in the semiconductor field and the transition in the wavelength during exposure from DUV (e.g., 193 nm) to EUV (e.g., 13.5 nm). In order to ensure that a mask satisfies these accuracy requirements and a microstructured component produced thereby also has the desired properties and manner of functioning, a mask is checked by use of suitable methods in inspection and/or metrology apparatuses before use in a projection exposure apparatus.

In the case of known inspection and/or metrology apparatuses, the object to be checked—i.e., for example, a mask for producing microstructured components—is illuminated by an illumination source in such a way that either the radiation partially reflected back off the object or the partially transmitted radiation is incident on a sensor through an imaging optical unit, the sensor data of which sensor can then be suitably evaluated.

The sensor can be, e.g., an imaging sensor, from the sensor data of which (in general) two-dimensional image representations of a specific measurement variable, namely of the radiation intensity, can be derived. In this case, an imaging sensor itself can be configured in an areal fashion and capture all the measurement variables for a specific image representation all at once; however, it is also possible that an imaging sensor is configured only in a point-type or linear fashion, namely as a point or line sensor, and thus can only determine portions of the measurement variables required for a desired image representation all at once, while the further measurement variables required for the image representation have to be captured in further steps in each case after suitable realignment of the imaging sensor and/or of the object in order to obtain the desired image representation of the measurement variables as a result. In this case, the described realignment of the imaging sensor and/or of the object can also be realized as a continuous relative movement of the two components with respect to one another, wherein the sensor then practically continuously captures data which can be combined to form a two-dimensional image representation. A corresponding process is also referred to as “scanning.”

Inter alia in order to obtain higher-contrast images, it is known to provide a plurality of imaging sensors which are arranged in such a way that during the continuous scanning movement they capture the same regions of the object successively with a temporal offset. The images of a specific region of the object captured by the various imaging sensors can then be additively superimposed in order to obtain a high-contrast image representation of the region in question. In order that the images from the various sensors do actually image the same region of the object, it is necessary for the various sensors to capture their respective images with a temporal offset, wherein the necessary temporal offset results from the geometric arrangement of the sensors, the imaging scale of the imaging optical unit and the scanning speed—i.e., the relative speed between object and sensors.

Time Delay Integration (TDI) sensors also work according to a similar principle, and in their case the sensor is subdivided into a plurality of portions which, during a scan, successively capture the same region of the object, so that the images captured by the individual portions can be additively superimposed. This necessitates suitable adaptation of the operating frequency of a TDI sensor to the scanning speed.

It has been found that during a scanning process of an inspection or metrology apparatus, the imaging scale of a lens used in this process, the geometric arrangement of the plurality of imaging sensors or else the imaging sensors themselves change, e.g., on account of heat influences. Precisely these effects can lead to image blurring when captured images of the same region are additively superimposed—as is also carried out in principle with TDI sensors—and inspection is disadvantageously affected by said image blurring.

It is an aspect of the present invention to provide a method and a device which avoid or at least reduce the disadvantages from the prior art.

### SUMMARY

This aspect is achieved by a method according to Claim 1 and also a device according to Claim 11. The dependent claims relate to advantageous developments.

Accordingly, the invention relates to a method for capturing images of micro-and/or nanostructures, in particular of structures on microlithographic masks, using an image capturing unit comprising at least two image capturing sensors arranged in such a way that, from an object guided past the image capturing unit at a constant speed in a predefined direction in the image region, by use of the image capturing sensors, they each successively capture the same region of the surface of the object, wherein the image capturing sensors are controlled by a temporal offset resulting from the speed by use of a predefined factor in such a way that a group of images captured by the individual image capturing sensors in each case image the same region of the surface of the object and can be additively superimposed, characterized by the steps of:
determining a variable characteristic of the position correspondence of the captured images of the same region in the images of a group captured by the individual image capturing sensors; and
if the characteristic variable determined is not optimal: adapting the predefined factor according to the characteristic variable determined.

Furthermore, the invention relates to a device for capturing images of micro-and/or nanostructures, in particular of structures on microlithographic masks, comprising an illumination device for illuminating an object arranged on an object stage with illumination radiation and an image capturing unit for capturing the illumination radiation transformed by the object, wherein the image capturing unit comprises at least two image capturing sensors which each capture individual adjacent regions of the object arranged on the object stage, and the object stage is designed for moving the object in at least one direction, so that the image capturing sensors can each successively capture an image of the same region of the surface of the object arranged on the object stage, wherein a controller is provided, to control the image capturing sensors depending on the speed of movement of the object on the object stage for capturing the same region of the surface with a suitable time offset in such a way that the images of the same region of the surface captured by the individual image capturing sensors can be additively merged to form an image of the region of the surface, and wherein the controller is designed for carrying out a method according to the invention.

The invention has recognized that the influences that can lead to image blurring when capturing images of micro- and/or nanostructures, in particular of structures on microlithographic masks, cannot be completely eliminated. Therefore, the invention provides for compensating for these influences by use of a suitable (re)calibration.

The invention makes use of the fact that in image capturing units comprising at least two image capturing sensors arranged suitably for the scanning, the latter are controlled in such a way that a group of images of in principle the same region on the surface of the object is in each case captured. By determining a characteristic variable reflecting the actual position correspondence of the images of the same region, it is possible to determine whether the images recorded by the different image capturing units actually image the same region of the object in such a way that they can be additively superimposed without additional image blurring arising in the process. If this is not the case, for example, because the distance between the sensors has changed on account of thermal expansion, the factor used to determine the time offset for the capture of the images by the various image capturing sensors from the speed at which the object is guided past the image capturing unit can be changed, in order thus to improve the position correspondence of subsequently captured images.

If the characteristic variable used for the position correspondence is a variable which also depends on the micro-and/or nanostructures in the captured region, the position correspondence may not be able to be directly determined from a group of captured images of the same region. In such a case, it is preferred if at least one further variable characteristic of the position correspondence of the captured images of the same region in the images of a group captured by the individual image capturing sensors is determined, wherein at least one portion of the images of a group is transformed in such a way as if the images were captured with a changed predefined factor. The transformation in question can generally be achieved by laterally displacing at least one image of the group, which ultimately corresponds to an earlier or later capture of the image in question in comparison with the actual temporal offset. If at least one further characteristic variable is determined on the basis of a group of images transformed in this way, it is possible, by comparing the characteristic variables determined, to ascertain whether the characteristic variable determined on the basis of the non-transformed group of images represents the optimum. If not—e.g., because a characteristic variable determined on the basis of a group of at least partially transformed images is more advantageous, the predefined factor can be suitably adapted. The non-transformed group of images or else the group of images with the best characteristic value for the position correspondence can moreover continue to be used for the actual inspection; the remaining groups of images can be discarded.

It is advantageous if at least two further variables characteristic of the position correspondence of the captured images of the same region in the images of a group captured by the individual image capturing sensors are determined, wherein at least one portion of the images of one group is transformed in such a way as if the images were captured with a predefined factor increased by a delta, and the at least one portion of the images of the other group is transformed in such a way as if the images were captured with a predefined factor decreased by the delta.

Irrespective of this, it is preferred if the direction and/or the absolute value in and/or by which the predefined factor is to be adapted is determined from the plurality of characteristic variables. If a total of at least three characteristic variables have been determined, two of which are based on groups comprising transformed images, it is possible regularly to derive the direction in which the predefined factor is to be changed—i.e., increased or decreased—in order to improve the characteristic variable on the basis of non-transformed images. That can be repeated until the characteristic variable in question is optimal. It is also easily possible to determine a higher number of characteristic variables on the basis of images transformed differently in each case, this resulting in respective support points for a curve to be determined, e.g., by a regression analysis. A curve determined in this way can be taken as a basis for directly reading off the value to which the predefined factor is to be set in order to achieve a characteristic variable that is at least close to the optimum on the basis of non-transformed images of a group.

The characteristic variable used can be, e.g., the contrast of the additively superimposed image constituted from the images of a group. This contrast can be assumed to have, given optimal position correspondence of the captured images of the same region, in general a single maximum, but at least an unambiguously identifiable primary maximum. By way of example, the root mean square over all or some of the image points of the additively superimposed images of a group or the standard deviation vis-à-vis the mean value (both determined over all or some of the image points of a recorded image) can be used as a value for the contrast. This variable, too, has a single optimum or an unambiguously identifiable primary optimum in conjunction with which an optimal position correspondence of the captured images of the same region is attained. It is also possible to use the reciprocal of the contrast as a characteristic variable.

It is also possible for the characteristic variable determined to be the spatial offset—determined by image correlation—of the captured images of the same region in the images of a group captured by the individual image capturing sensors. Suitable methods for image correlation, such as e.g., a threshold point-based image evaluation method, a centroid-based image evaluation method, a symmetry correlation image evaluation method or a cross-correlation image evaluation method, are known from the prior art. The spatial offset determined must be minimal or equal to zero for optimal position correspondence of captured images of the same region.

It is possible and preferred for a necessary adaptation of the factor in order to minimize the spatial offset to be calculated from the spatial offset determined. Taking into account the speed at which the object is guided past the image capturing unit, it is possible to derive directly from an ascertained spatial offset the absolute value by which the predefined factor is to be increased or decreased in order to minimize the spatial offset.

It is preferred if at least one portion of the image capturing sensors are TDI sensors, i.e., “time delay integration” sensors (TDI sensors). Corresponding sensors are known from the prior art.

It is possible for the readout speed of the individual sensor series of the TDI sensors to be adapted according to the predefined factor for determining the temporal offset. If it is assumed that effects that arise crucially from a change in the pose of the individual image capturing sensors with respect to one another—e.g., on account of thermal expansion—and require an adaptation of the factor in question are reflected in a corresponding thermal expansion of a TDI sensor, whereby the expansion of the individual sensor series of the TDI sensor changes, it is possible to ensure by use of a suitable adaptation of the readout speed that the image captured by the TDI sensor has the highest possible contrast. It is possible to take account of the fact that a TDI sensor may have a different coefficient of thermal expansion than the coefficient of thermal expansion that is crucial for the temperature-dependent change in the distance between the sensors. In this regard, a TDI sensor is often composed of silicon, while the supporting structure to which the sensors are secured may be composed of metal, e.g., steel.

It is also possible at times to change the readout speed of at least one image capturing sensor designed as a TDI sensor and to leave the readout speed of at least one other image capturing sensor designed as a TDI sensor unchanged in order, for images of the same region of the surface of the object captured by the image sensors in question, then in each case to determine a variable characteristic of the contrast, to calculate an improved readout speed from the characteristic variables determined and to adapt the readout speed of all image capturing sensors designed as TDI sensors to the improved readout speed. Depending on the number of characteristic variables determined, the improved readout speed can be changed step by step proceeding from the last readout speed used, until an optimum is reached. Once a sufficient number of characteristic variables have been determined, a readout speed at least close to the optimum can be determined directly by use of suitable regression analysis.

If an improved or optimal readout speed for the image capturing sensors designed as TDI sensors is found in this way, this readout speed can also be used as a characteristic variable for the position correspondence and be used for a possible adaptation of the predefined factor.

For explanation of the device according to the invention, reference is made to the statements above.

### BRIEF DESCRIPTION OF DRAWINGS

The invention will now be described by way of example on the basis of an advantageous embodiment with reference to the accompanying drawings, in which:

FIG. 1: shows a schematic illustration of a first exemplary embodiment of a device according to the invention;

FIGS. 2, 3: show schematic illustrations for implementing an embodiment variant of the method according to the invention using the device according to FIG. 1; and

FIGS. 4-6: show schematic illustrations for implementing alternative embodiment variants.

### DETAILED DESCRIPTION

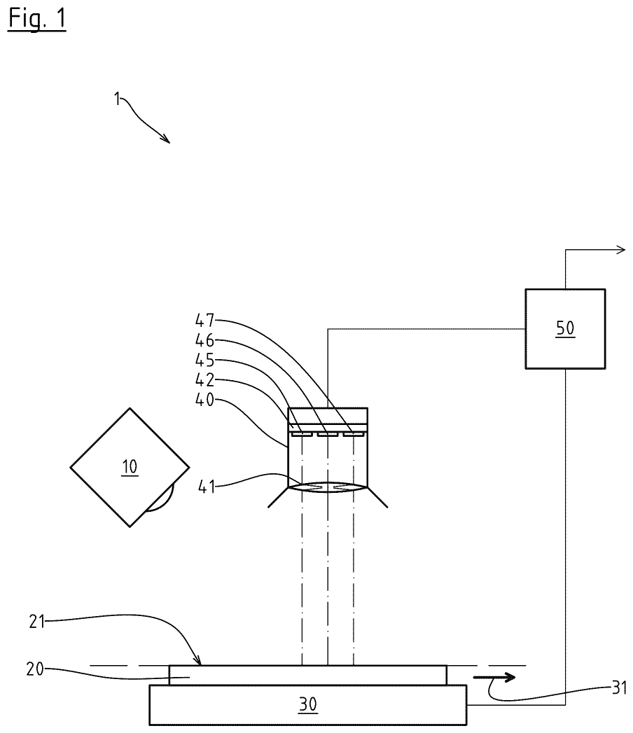

FIG. 1 schematically illustrates a first exemplary embodiment of a device 1 according to the invention for capturing images of micro-and/or nanostructures on an object 20. The object 20 to be captured as an image is a reflective mask, having corresponding structures on the surface. Radiation incident on the object is reflected, in principle, wherein the incident radiation is partially transformed by the micro-and/or nanostructures, e.g., by parts of the radiation being absorbed.

Especially if a microlithographic mask is involved, the object 20 can have an aspect ratio of between 1:1 and 1:3, preferably between 1:1 and 1:2 and particularly preferably of 1:1 or 1:2. The object 20 can in this case be substantially rectangular and preferably has a length and width of 5 to 7 inches (12.70 to 17.78 cm), with further preference a length and width of 6 inches (15.24 cm). As an alternative thereto, the object 20 can have a length of 5 to 7 inches (12.70 cm to 17.78 cm) and a width of 10 to 14 inches (25.40 cm to 35.56 cm), preferably a length of 6 inches (15.24 cm) and a width of 12 inches (30.48 cm).

The device 1 comprises an illumination device 10, by which the object 20 can be sufficiently illuminated. In this case, the illumination device 10 is adapted to the object 20 in such a way that the illumination radiation is sufficiently reflected by the object 20 or at least parts of the micro-and/or nanostructures, such that the image capturing unit 40 can capture the illumination radiation transformed by the object 20 and image-pertaining information concerning the surface of the object 20 actually arises from the illumination radiation thus captured. For this purpose, the wavelength of the illumination radiation must be low enough that the micro- and/or nanostructures can actually be imaged. If the object 20 is, e.g., a microlithographic mask for microlithography in the EUV range, the illumination radiation of the illumination device 10 is regularly likewise in the EUV range, i.e., between 5 nm and 30 nm, preferably at 13.5 nm, since it is only at such a wavelength that the micro- and/or nanostructures typically situated on corresponding microlithographic masks can actually be imaged. Moreover, the reflective properties of corresponding microlithographic masks are optimized towards corresponding wavelengths.

The object 20 whose top side 21 is illuminated by the illumination device 10 is arranged on an object stage 30, by which the object 20 can in particular also be moved in the direction indicated by the arrow 31.

For actually capturing the micro-and/or nanostructures on the surface of the object 20, an image capturing unit 40 is provided, by which the illumination radiation of the illumination device 10 that has been reflected and transformed by the object 20 is captured in such a way as ultimately to give rise to a two-dimensional image representation of the micro-and/or nanostructures on the surface of the object 20. Changing the distance between object 20 and image capturing unit 40 makes it possible to focus the image capturing unit 40.

For this purpose, the image capturing unit 40 has an optical unit 41, which is telecentric on the object side. The optical unit 41, which is merely indicated schematically in FIG. 1, comprises exclusively mirrors as optical elements, which are suitably configured for reflecting the illumination radiation used, e.g., EUV radiation. In the case of illumination radiation in wavelength ranges for which transmissive optical elements, e.g., lens elements, are also known, the optical unit 41 can also comprise such optical elements.

The image capturing unit 40 comprises three image capturing sensors 45, 46, 47, which are secured to a common frame 42. The three image capturing sensors 45, 46, 47 are “time delay integration” sensors (TDI sensors) that each capture individual regions of the object 20 lying one behind the other in the direction of movement of the object 20 as indicated by the arrow 31. During movement of the object 20 with the aid of the object stage 30 in direction 31 a specific region on the surface 21 of the object 20 successively passes through the capture regions of the three image capturing sensors 47, 46, 45.

The device 1 furthermore comprises a controller 50, which is connected both to the image capturing unit 40 and to the object stage 30 and controls at least the respective movement thereof. The control of the object stage 30 and also the capture by the image capturing sensors 45, 46, 47 are carried out according to the known principle of scanning: The image capturing sensors 45, 46, 47 are controlled by the controller 50 depending on the speed of the object 20 in direction 31 with a temporal offset such that they each capture an image of the same region on the surface 21 of the object 20. The corresponding group of images can then—e.g., by the controller 50—be additively superimposed in order to obtain an image of the region in question of the surface 21 of the object 20 with increased contrast, which image can be forwarded for further inspections.

During operation of the device 1, the imaging scale of the optical unit 41 and/or the expansion of the frame 42 may change, e.g., on account of heat input, whereby the pose of the image capturing sensors 45, 46, 47 with respect to one another also changes. It is also possible that the image capturing sensors 45, 46, 47, designed as TDI sensors, themselves expand. Subsequently, (additional) blur may be introduced into the images captured by the individual image capturing sensors 45, 46, 47 or else into the image resulting from additive superimposition of the images of a group, i.e., of the images recorded by different image sensors 45, 46, 47, each of said images imaging the same region of the surface 21 of the object 20.

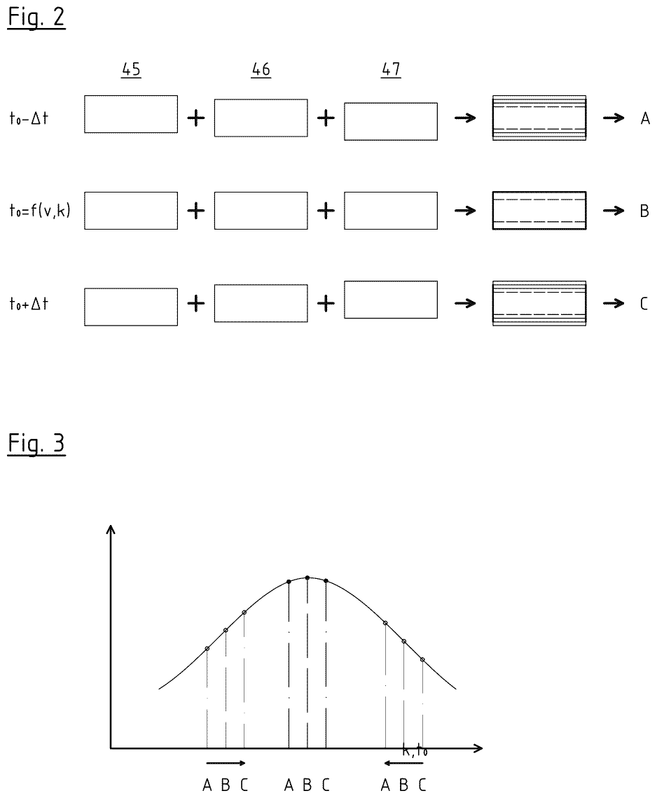

In order to reduce these effects and the associated disadvantages for the inspection of the object 20, the controller 50 is designed to carry out a method according to the invention, as is explained below with reference to FIGS. 2 and 3.

The images of a group (which therefore in principle image the same region of the surface 21 of the object 20) captured by the image capturing sensors 45, 46, 47 with the temporal offset of t₀ resulting inter alia from a predefined factor k and the speed v of the object 20 in direction 31 are additively superimposed. From a central region of the resulting image, the contrast is determined as a characteristic variable B.

Analogously thereto, comparable contrasts are also determined as characteristic variables A and C. For the determination of these contrasts, the images from the image capturing sensors 45 and 47 are transformed by translation in such a way that upon the additive superimposition they give the impression of having been created with a temporal offset of t₀+Δt or t₀−Δt, which ultimately corresponds to a change in the predefined factor k by ±Δk.

If the characteristic variables A, B and C are present, assuming that the characteristic variable B—as is the case with contrast—is likewise optimal given an optimal position correspondence of the images of a group, it is possible to determine whether and, if so, in which direction the predefined factor k needs to be changed in order to achieve as optimal position correspondence as possible.

This is illustrated in FIG. 3: If the characteristic variable B is smaller than the characteristic variable C, but larger than the characteristic variable A, the temporal offset for the recording of the individual images and thus also the predefined factor k must be increased (illustrated on the left); if the proportions are exactly the opposite, the predefined factor k is to be decreased (illustrated on the right). In this way, the state is approached in which the characteristic variable B is larger than the variables A and C, whereby the temporal offset t and thus the predefined factor k are at least close to the optimum at which the images of a group from the individual image capturing sensors 45, 46, 47 have a high position correspondence (illustrated in the middle). The optimum is regularly achieved in the event that not only do the abovementioned proportions exist, but furthermore the characteristic variables A and C are equal in magnitude.

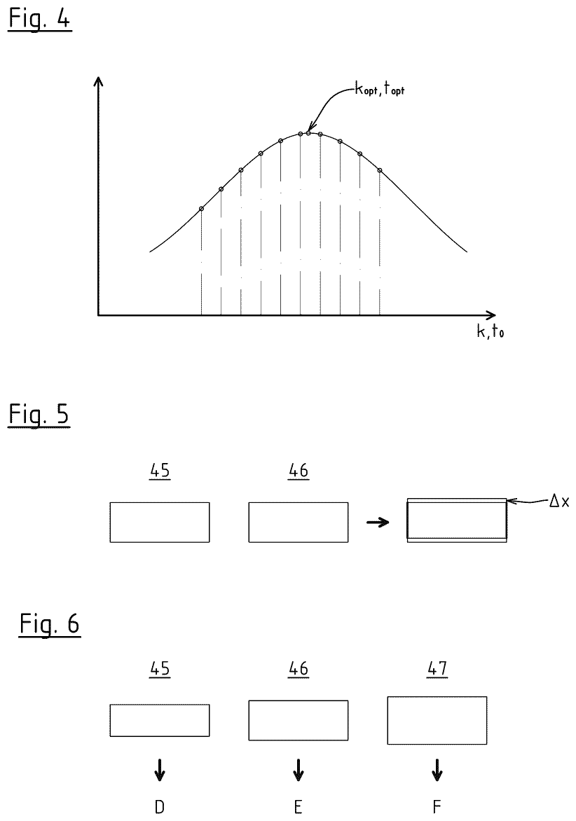

It is possible to determine not just two additional characteristic variables A and C on the basis of transformed images, but rather a much larger number. If this is the case, it is possible—as illustrated in FIG. 4—to determine a profile of the characteristic variable by use of a regression analysis, which then not only yields the direction of the necessary change, but enables the optimal temporal offset tₒₚₜ and thus the optimal predefined factor kₒₚₜ to be directly determined.

In the embodiment variant according to FIG. 5, the spatial offset Δx is determined from two images of the same region on the surface 21 of the object 20, said images having been captured by different image capturing sensors 45, 46, by use of suitable image processing methods. From this spatial offset, the optimal predefined factor kₒₚₜ can be determined taking into account the speed of movement of the object 20 in direction 31.

In the embodiment variant according to FIG. 6, image capturing sensors 45 and 47, each configured as a TDI sensor, are operated at times with a different readout speed deviating from the currently predefined frequency, wherein the readout speed for the image capturing sensor 45 is higher, and that for the image capturing sensor 47 is below the predefined readout speed, while the image capturing sensor 46 is still operated at the currently predefined readout speed. For the images captured in this way of the same region of the object 20, it is possible to determine respective characteristic variables D, E and F, e.g., the contrast in each case. In the case of TDI sensors, it holds true that given an optimal predefined readout speed, the optimal contrast is established as well. In a manner comparable with the illustration in FIG. 3, it is thus possible to determine from the characteristic variables D, E, and F the direction in which the readout speed needs to be changed in order to approach the optimal readout speed.

The adaptation of the predefined factor that is determined on the basis of the images of a group can moreover in principle also be applied to the change in the readout speed in the case of TDI sensors. Conversely, it is also possible to derive a change in the predefined factor for the temporal offset from an optimized readout speed for a TDI sensor. Since the thermal expansion is generally as isotropic as a possible change in the imaging scale, the computational correction determined for the scanning direction using the method according to the invention can also be applied to a direction perpendicular to the scanning direction.

In some implementations, the controller 50 can include one or more computers (or computing devices), each computer can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, each of the one or more computers can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage medium or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention.

What is claimed is:

1. A method for capturing images of micro-and/or nanostructures, in particular of structures on microlithographic masks, using an image capturing unit comprising at least two image capturing sensors arranged in such a way that, from an object guided past the image capturing unit at a constant speed in a predefined direction in the image region, by use of the image capturing sensors, they each successively capture the same region of the surface of the object, wherein the image capturing sensors are controlled by a temporal offset resulting from the speed by use of a predefined factor in such a way that a group of images captured by the individual image capturing sensors in each case image the same region of the surface of the object and can be additively superimposed, the method comprising:
determining a variable characteristic of the position correspondence of the captured images of the same region in the images of a group captured by the individual image capturing sensors; and
if the characteristic variable determined is not optimal: adapting the predefined factor according to the characteristic variable determined.

2. The method of claim 1, further comprising:
determining at least one further variable characteristic of the position correspondence of the captured images of the same region in the images of a group captured by the individual image capturing sensors, wherein at least one portion of the images of a group is transformed in such a way as if the images were captured with a changed predefined factor;

3. The method of claim 2, wherein at least two further variables characteristic of the position correspondence of the captured images of the same region in the images of a group captured by the individual image capturing sensors are determined, wherein at least one portion of the images of one group is transformed in such a way as if the images were captured with a predefined factor increased by a delta, and the at least one portion of the images of the other group is transformed in such a way as if the images were captured with a predefined factor decreased by the delta.

4. The method of claim 2, further comprising:
determining from the plurality of characteristic variables the direction and/or the absolute value in and/or by which the predefined factor is to be adapted.

5. The method of claim 2, wherein the characteristic variable determined is the contrast, or the reciprocal thereof, of an image resulting from superimposing the images of a group of images of the same region of the surface of the object which were captured by the individual image capturing sensors.

6. The method of claim 1, wherein the characteristic variable determined is the spatial offset—determined by image correlation—of the captured images of the same region in the images of a group captured by the individual image capturing sensors.

7. The method of claim 6, wherein a necessary adaptation of the predefined factor in order to minimize the spatial offset is calculated from the determined spatial offset.

8. The method of claim 1, wherein at least one portion of the image capturing sensors are TDI sensors.

9. The method of claim 8, wherein the readout speed of the individual sensor series of the TDI sensors is adapted according to the factor for determining the temporal offset.

10. The method of claim 8, wherein at times, the readout speed of at least one image capturing sensor designed as a TDI sensor is changed, and the readout speed of at least one other image capturing sensor designed as a TDI sensor is left unchanged, in order to determine, for images of the same region of the surface of the object captured by the image sensors in question, in each case a variable characteristic of the contrast, to calculate an improved readout speed from the characteristic variables determined, and to adapt the readout speed of all image capturing sensors designed as TDI sensors to the improved readout speed.

11. A device for capturing images of micro- and/or nanostructures, in particular of structures on microlithographic masks, comprising an illumination device for illuminating an object arranged on an object stage with illumination radiation and an image capturing unit for capturing the illumination radiation transformed by the object, wherein the image capturing unit comprises at least two image capturing sensors which each capture individual adjacent regions of the object arranged on the object stage, and the object stage is designed for moving the object in at least one direction, so that the image capturing sensors can each successively capture an image of the same region of the surface of the object arranged on the object stage, wherein a controller is provided, to control the image capturing sensors depending on the speed of movement of the object on the object stage for capturing the same region of the surface with a suitable time offset in such a way that the images of the same region of the surface captured by the individual image capturing sensors can be merged to form an image of the region of the surface, wherein the controller is designed for carrying out a method according to claim 1.

12. The device of claim 11, wherein at least one portion of the image capturing sensors are TDI sensors.

13. The method of claim 12 wherein the readout speed of the individual sensor series of the TDI sensors is adapted according to the factor for determining the temporal offset.

14. The method of claim 12, wherein at times, the readout speed of at least one image capturing sensor designed as a TDI sensor is changed, and the readout speed of at least one other image capturing sensor designed as a TDI sensor is left unchanged, in order to determine, for images of the same region of the surface of the object captured by the image sensors in question, in each case a variable characteristic of the contrast, to calculate an improved readout speed from the characteristic variables determined, and to adapt the readout speed of all image capturing sensors designed as TDI sensors to the improved readout speed.

15. The device of claim 11 wherein the controller is configured to determine at least one further variable characteristic of the position correspondence of the captured images of the same region in the images of a group captured by the individual image capturing sensors, wherein at least one portion of the images of a group is transformed in such a way as if the images were captured with a changed predefined factor.

16. The device of claim 15 wherein the controller is further configured to determine at least two further variables characteristic of the position correspondence of the captured images of the same region in the images of a group captured by the individual image capturing sensors, wherein at least one portion of the images of one group is transformed in such a way as if the images were captured with a predefined factor increased by a delta, and the at least one portion of the images of the other group is transformed in such a way as if the images were captured with a predefined factor decreased by the delta.

17. The device of claim 15 wherein the controller is further configured to determine from the plurality of characteristic variables the direction and/or the absolute value in and/or by which the predefined factor is to be adapted.

18. The device of claim 15, wherein the characteristic variable determined is the contrast, or the reciprocal thereof, of an image resulting from superimposing the images of a group of images of the same region of the surface of the object which were captured by the individual image capturing sensors.

19. The device of claim 11 wherein the characteristic variable determined is the spatial offset—determined by image correlation—of the captured images of the same region in the images of a group captured by the individual image capturing sensors.

20. The device of claim 19 wherein the controller is configured to calculate a necessary adaptation of the predefined factor in order to minimize the spatial offset from the determined spatial offset.
